(19) United States
(12) Patent Application Publication
(10) Pub. No.: US 2025/0174525 A1
(43) Pub. Date: May 29, 2025

(54) RECESSED CLIP PAD FOR PASSIVE SURFACE MOUNT COMPONENT

(71) Applicant: Texas Instruments Incorporated, Dallas, TX (US)

(72) Inventors: John Carlo Molina, Limay (PH); Jason Colte, La Trinidad (PH)

(21) Appl. No.: 18/523,480

(22) Filed: Nov. 29, 2023

(51) Int. Cl. H01L 23/495; H01L 23/00; H01L 23/498

(52) U.S. Cl. CPC H01L 23/49527; H01L 23/49582; H01L 23/49589; H01L 23/49822; H01L 24/16; H01L 2224/16225

(57) ABSTRACT

An electronic device includes a semiconductor die attached to a lead frame or substrate, conductive first and second metal clips attached to the lead frame or substrate, a molded package structure that encloses the semiconductor die and has a top side with first and second recesses that extend into the molded package structure to top sides of the respective first and second metal clips, and an electronic component having conductive metal first and second terminals that extend into the respective first and second recesses and are electrically connected to the top sides of the respective first and second metal clips.

### BACKGROUND

Integrated power modules and other packaged electronic devices can include a semiconductor die and one or more passive components in a shared package structure and may have a surface mount technology (SMT) component mounted outside the package. However, non-wetting or insufficient soldering of the SMT component terminals and/or insufficient adhesive can dislodge the SMT component from the package assembly.

### SUMMARY

In one aspect, an electronic device includes a semiconductor die attached to a lead frame or substrate, conductive first and second metal clips attached to the lead frame or substrate, a molded package structure, and an electronic component. The molded package structure encloses the semiconductor die and has a top side with first and second recesses that extend into the molded package structure to top sides of the respective first and second metal clips, and the electronic component has conductive metal terminals that extend into the respective recesses and are electrically connected to the top sides of the respective first and second metal clips.

In another aspect, a system includes a circuit board having conductive metal pads and an electronic device attached to the circuit board. The electronic device includes conductive metal leads electrically connected to respective ones of the conductive metal pads, as well as a semiconductor die attached to a lead frame or substrate, conductive first and second metal clips attached to the lead frame or substrate, a molded package structure, and an electronic component. The molded package structure encloses the semiconductor die and has a top side with first and second recesses that extend into the molded package structure to top sides of the respective first and second metal clips, and the electronic component has conductive metal terminals that extend into the respective recesses and are electrically connected to the top sides of the respective first and second metal clips.

In a further aspect, a method of fabricating an electronic device includes attaching a semiconductor die to a lead frame or substrate, attaching conductive first and second metal clips to the lead frame or substrate, and forming a molded package structure that encloses the semiconductor die and has a top side. The method also includes removing molded material from a top side of the molded package structure to form first and second recesses that extend into the molded package structure to top sides of the respective first and second metal clips, and electrically connecting conductive metal first and second terminals of an electronic component through the recesses to the top sides of the respective first and second metal clips.

### BRIEF DESCRIPTION OF THE DRAWINGS

FIG. 1 is a partial top perspective view of an electronic device attached to a printed circuit board of a system, including an electronic component attached to the top side of the electronic device.

FIG. 1A a is a partial sectional side elevation view of the electronic device taken along line 1A-1A a of FIG. 1.

FIG. 2 is a flow diagram showing a method for making an electronic device according to another aspect.

FIG. 3 is a partial sectional side elevation view of a multilevel package substrate undergoing a die attach process.

FIG. 4 is a partial sectional side elevation view of the multilevel package substrate undergoing a surface mount component attachment process.

FIG. 5 is a partial sectional side elevation view of the multilevel package substrate undergoing a metal clip attachment process.

FIG. 6 is a partial sectional side elevation view of the multilevel package substrate undergoing a thermal solder reflow process.

FIG. 7 is a partial sectional side elevation view of the multilevel package substrate undergoing a molding process.

FIG. 8 is a partial sectional side elevation view of the multilevel package substrate undergoing a laser ablation process that exposes portions of top sides of the metal clips.

FIG. 9 is a partial sectional side elevation view of the multilevel package substrate undergoing an adhesive formation process.

FIG. 10 is a partial sectional side elevation view of the multilevel package substrate undergoing a solder paste formation process.

FIG. 11 is a partial sectional side elevation view of the multilevel package substrate undergoing an electronic component attachment process.

FIG. 12 is a partial sectional side elevation view of the multilevel package substrate undergoing a thermal solder reflow process.

FIG. 13 is a partial sectional side elevation view of the multilevel package substrate undergoing an optional second molding process.

FIG. 14 is a partial sectional side elevation view of the multilevel package substrate undergoing a package separation process.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”.

Unless otherwise stated, “about,” “approximately,” or “substantially” preceding a value means +/−10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc., may be referred to herein as first, second, third, etc., such as first and second terminals, first, second, and third, wells, etc., for ease of description in connection with a particular drawing, where such are not to be construed as limiting with respect to the claims. Various disclosed structures and methods of the present disclosure may be beneficially applied to manufacturing an electronic device such as an integrated circuit. While such examples may be expected to provide various improvements, no particular result is a requirement of the present disclosure unless explicitly recited in a particular claim.

Disclosed examples include electronic devices, fabrication methods, and systems with a device package structure that encloses a semiconductor die and has a top side with recesses that extend into the package structure to top sides of the respective first and second metal clips. An electronic component of the electronic device has conductive metal terminals that extend into the respective recesses and are electrically connected to the top sides of the respective metal clips. These examples mitigate or overcome manufacturing and performance problems associated with devices having metal clips with the top sides that are flush with the top of a molded package structure, where non-wetting or insufficient soldering of the component terminals and/or insufficient adhesive can dislodge the component from the package assembly. In addition, the described examples can facilitate device height reduction and enhance the adherence of the electronic component to the clips and the package structure.

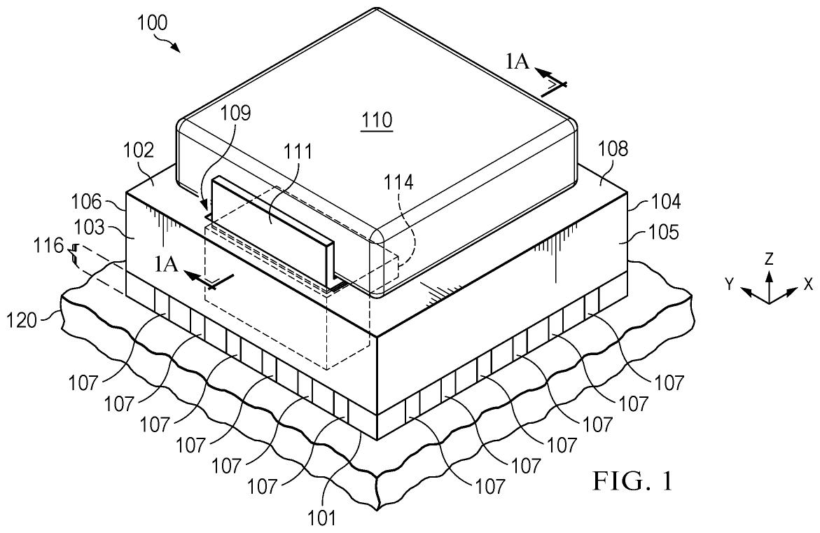

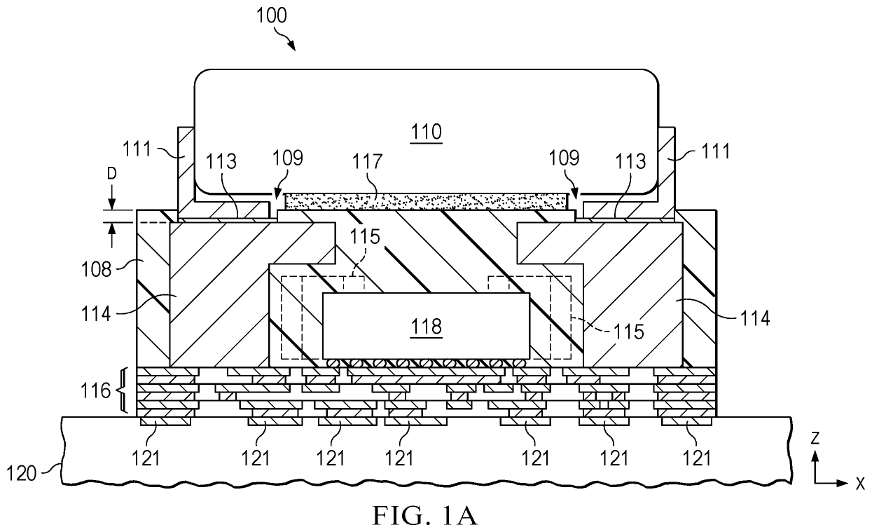

FIGS. 1 and 1A show a system with an example electronic device 100 positioned in an example three-dimensional space with a first direction X, a perpendicular (orthogonal) second direction Y (FIG. 1), and a third direction Z that is perpendicular (orthogonal) to the respective first and second directions X and Y. Structures or features along any two of these directions are orthogonal to one another. As shown in FIG. 1, the electronic device 100 has opposite first and second (e.g., bottom and top) sides 101 and 102, respectively, which are spaced apart from one another along the third direction Z in the illustrated position. The electronic device 100 also has opposite third and fourth sides 103 and 104 (e.g., lateral sides) that are spaced apart from one another along the first direction X, and fifth and sixth sides 105 and 106 that are spaced apart from one another along the second direction Y in the illustrated position.

The electronic device 100 is attached to a circuit board 120 having conductive metal pads 121 in the illustrated system. The electronic device 100 includes conductive metal leads 107 that are electrically connected to respective ones of the conductive metal pads 121 of the circuit board 120. The electronic device 100 includes a molded package structure 108 that has a top side with first and second recesses 109 that extend into the molded package structure 108 by a distance D. The illustrated electronic device 100 includes an electronic component 110 having conductive metal first and second terminals 111 that extend into the respective first and second recesses 109. The component terminals 111 are electrically coupled to top sides of respective first and second metal clips 114 by solder 113 (FIG. 1A). The example electronic device also includes internal capacitors 115 (FIG. 1A) enclosed within the molded package structure 108.

As further shown in FIG. 1A, the molded package structure 108 also encloses a semiconductor die 118. In this example, the semiconductor die 118 includes one or more electronic components, such as transistors, diodes, etc., and includes conductive metal features that provide electrical connections to one or more of the conductive metal leads 107 and to other components of the electronic device 100.

The semiconductor die 118, is attached to a multilevel package substrate 116 that includes the conductive metal leads 107. In another example, the electronic device can include remnant elements of a starting lead frame (not shown) and may include other electrical interconnections (e.g., bond wires, not shown) to form electrical interconnections of components of the semiconductor die 118, the conductive metal leads 107, and any additional components or conductive structures integrated into the electronic device, including capacitors 115, the electronic component 110, and the conductive metal clips 114.

The electronic component 110 in one example is a surface mount technology (SMT) component having a first terminal 111 extending into the first recess 109 and electrically connected to the top side of the first metal clip 114, and a second terminal 111 extending into the second recess 109 and electrically connected to the top side of the second metal clip 114. In the illustrated example, the semiconductor die 118 is flip chip attached to a top side of the multilevel package substrate 116, with die terminals soldered to corresponding conductive features on a top level of the substrate 116. The substrate 116 in this example includes multiple levels with conductive metal trace and via features. In this example, one or more peripheral trace and/or lead features of the substrate 116 form the conductive metal leads 107 of the electronic device. In this example, moreover, bottom metal features of the multilevel package substrate 116 are electrically coupled by solder (not shown) to corresponding ones of the conductive metal pads 121 of the system circuit board 120.

The example electronic device 100 includes adhesive 117 (e.g., glue, FIG. 1A). The adhesive 117 in one example extends between the top side of the molded package structure 108 and a portion of the bottom side of the electronic component 110. The adhesive 117 helps adhere the bottom side of the electronic component 110 to a portion of the top side of the molded package structure 108. In another implementation, the adhesive 117 can be omitted. Where included as shown in the illustrated example, the adhesive 117 provide structural support and helps adhere the electronic component 110 to the top side of the molded package structure 108, in addition to the solder connections 113 of the component terminals 111 to the top sides of the conductive metal clips 114.

The conductive first and second metal clips 114 are each attached to corresponding top side conductive metal features of the substrate 116. The first and second electronic component terminals 111 are individually connected by the solder connections 113 to the top sides of the respective first and second metal clips 114. The conductive metal clips 114 provide electrical connection of the terminals 111 of the electronic component 110 to corresponding circuit nodes of the system and/or of the electronic device 100.

In one example, the electronic device 100 is an integrated power module with one or more transistors of the semiconductor die 118 operatively interconnected to the capacitors 115 and the electronic component 110 to provide a power converter circuit, such as a boost converter, buck converter, buck-boost converter, cuk converter, etc. In one example, the electronic component 110 is an inductor. In other examples, other forms and types of electronic component 110 can be used, for example, where the electronic component 110 is a passive SMT components such as a resistor, a capacitor, an inductor, etc. and/or an active or switching type component, such as a diode, a transistor, etc. The electronic component 110 in the illustrated example is an SMT inductor component having leads that opposite ends thereof and is configured for surface mounting by solder connections to a printed circuit board or other host system. In the illustrated implementation, the component terminals 111 are soldered by SMT attachment techniques and the solder 113 (FIG. 1A) to the top sides of the conductive metal clips 114. This provides structural attachment and support as well as electrical interconnection of the electronic component 110 to the metal clips 114, and the structural support can be enhanced or facilitated by optional use of the adhesive 117 as shown in FIG. 1A.

The recesses 109 of the molded package structure 108 provide channels that facilitate formation of the solder 113 along at least portions of the top sides of the prospective conductive metal clips 114, and also mitigate or prevent the weight of the electronic component 110 from causing lateral movement of the solder 113 during solder reflow operations, and thereby facilitate providing adequate solder thickness (e.g., along the third direction Z) to prevent or mitigate nonwetted solder joints and help to ensure proper attachment and mechanical support of the electronic component 110 on the electronic device 100. In addition, the recesses 109 in one example are formed by laser ablation or other material removal process from an initially over molded package structure 108, and the use of laser ablation during fabrication provides a clean surface at the top sides of the conductive metal clips 114 to further facilitate proper solder connections between the electronic component terminals 111 and the top sides of the conductive metal clips 114.

The electronic component 110 in one example has a vertical height (e.g., along the third direction Z in the illustrated orientation) that is greater than the height of the remainder of the electronic device 100 including the molded package structure 108 and the height of the substrate 116. The provision of the recesses 109 in the top side of the molded package structure 1084 solder connection of the electronic component terminals 111 to the top sides of the conductive metal clips 114 helps reduce the overall height (along the third direction Z) of the electronic device 100.

Moreover, the solder connection of the electronic component 110 through the recesses 109 helps control overall device height even in the presence of dimensional tolerance variations in other components of the device 100, for example, the Z-direction thickness of the multilevel package substrate 116, solder connections between the substrate 116 and the conductive metal clips 114, and dimensional variations in the Z-direction height of the metal clips 114.

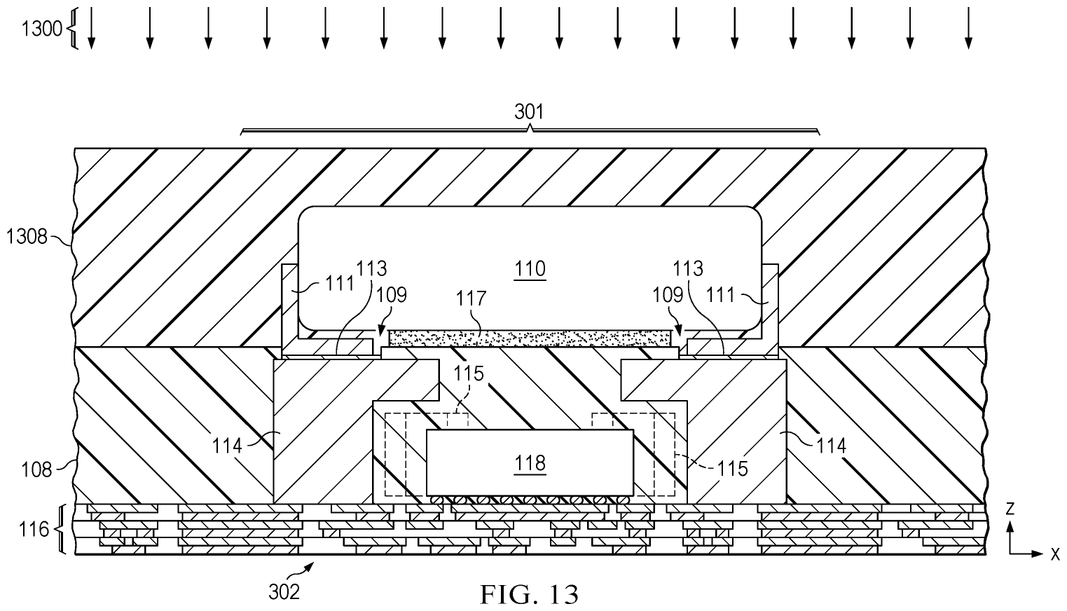

The electronic device 100 in one example can include a second molded package structure 1308 that encloses the electronic component 110, as illustrated and described below in connection with FIG. 13, although not a strict requirement of all possible implementations.

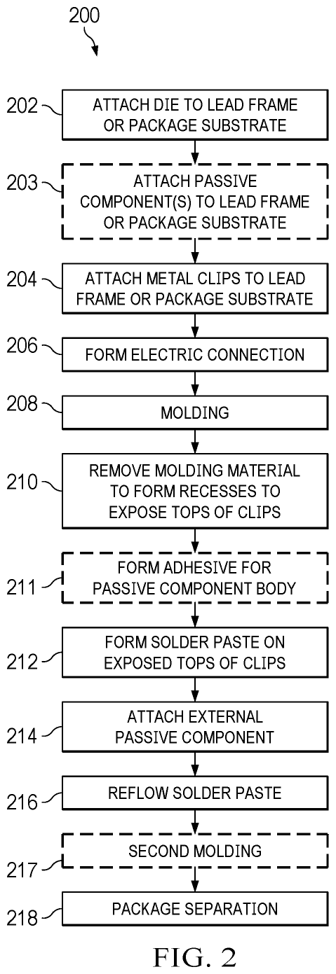

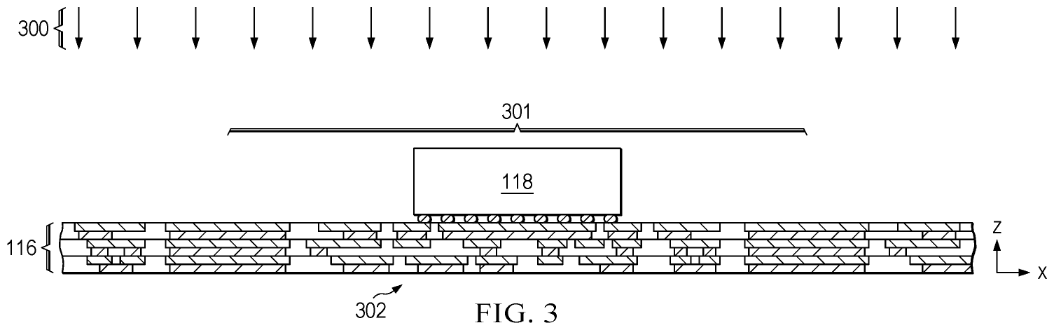

Referring also to FIGS. 2-14, FIG. 2 shows an example method 200 for making an electronic device and FIGS. 3-14 illustrate one or more implementations of the example electronic device 100 undergoing fabrication processing according to the method 200. The method 200 is illustrated in connection with the multilevel package substrate-based electronic device 100 described above. In another implementation, the packaging process starts with a starting lead frame (not shown). In the illustrated implementation, a starting multilevel package substrate 116 is located on a fixture (not shown). In this example, the substrate 116 is formed as a panel array including rows and columns of unit areas 301 as shown in FIG. 3, and the individual unit areas 301 correspond to respective instances of the prospective finished packaged electronic devices 100 after package processing.

The method 200 begins at 202 in FIG. 2 with die attach processing. FIG. 3 shows one example, in which a die attach process 300 is performed that attaches an instance of the semiconductor die 118 to corresponding conductive metal features on the top side of the multilevel package substrate 116 in each respective unit area 301 of the substrate panel array. The die attach process 300 can be automated, for example, using pick and place equipment (not shown) that successively attaches an instance of the semiconductor die 118 in each of the unit areas 301.

In one implementation, the attachment process 300 performs flip chip type solder attachment in combination with subsequent thermal solder reflow processing at 206 in FIG. 2. The attachment can include an initial solder paste formation, such as by silk screening, printing, etc. that forms solder paste on to respective conductive metal features on the top side of the multilevel package substrate 116 prior to placement of the individual semiconductor dies 118 in each unit area 301. In another implementation, the conductive metal terminals (e.g., copper bumps, etc.) of the semiconductor die instances 118 are dipped or otherwise previously provided with solder before being engaged to the top sides of the conductive metal substrate features. In the illustrated example, multiple components and structures are to be attached to the substrate 116 (e.g., semiconductor dies 118, clips 114, capacitors 115), and a single process can be used to form solder paste on the necessary locations of the top side of the multilevel package substrate.

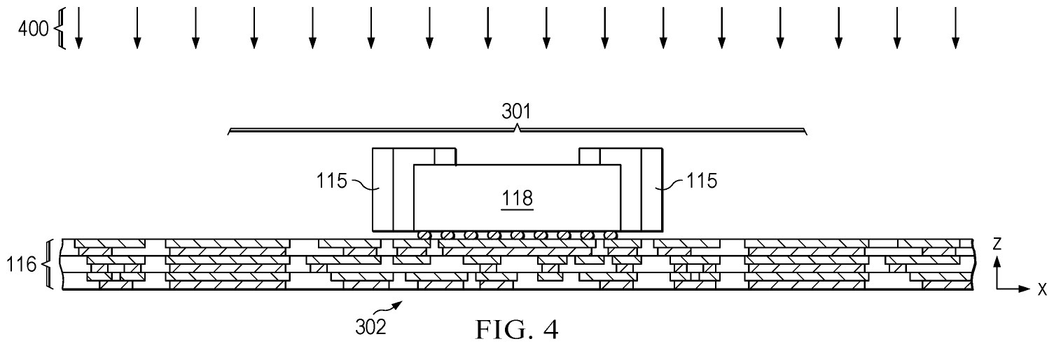

At 203 in FIG. 2, the method in one example includes attaching one or more passive components to the package substrate 116. FIG. 4 shows one example, in which a surface mount component attachment process 400 is performed that attaches the above-described capacitors 115 to corresponding conductive metal features in each unit area 301 on the top side of the multilevel package substrate 116, for example, using automated pick and place equipment. In one implementation, the capacitor attachment process 400 can be a continuation of the attachment process 300 used in attaching the semiconductor dies 118. The substrate conductive features to be connected with the terminals of the capacitor components 115 in one example are silkscreened or printed with solder paste prior to automated attachment or placement of the components 115.

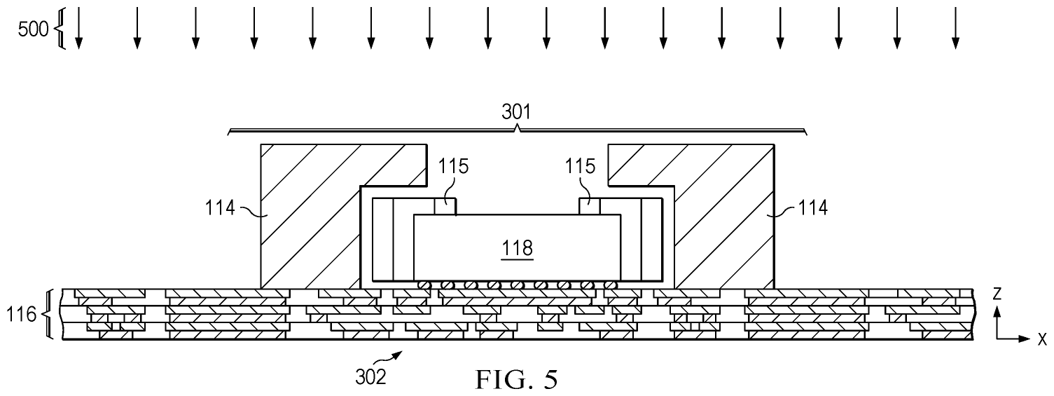

The method 200 continues at 204 and FIG. 2 with attaching the conductive first and second metal clips 114 to the substrate 116. FIG. 5 shows one example, in which in which a surface mount component attachment process 500 is performed that attaches the conductive metal clips 114 to corresponding conductive metal features in each unit area 301 on the top side of the multilevel package substrate 116, for example, using automated pick and place equipment. In one implementation, the metal clip attachment process 500 can be a continuation of the attachment process 300 used in attaching the semiconductor dies 118 or of the attachment process 400 used to attach the capacitors 115. The substrate conductive features to be connected with the conductive metal clips 114 in one example are silkscreened or printed with solder paste prior to automated attachment or placement of the conductive metal clips 114, for example, in a single solder paste silk screening or printing process prior to attachment of the semiconductor dies 118, the capacitors 115, and the conductive metal clips 114.

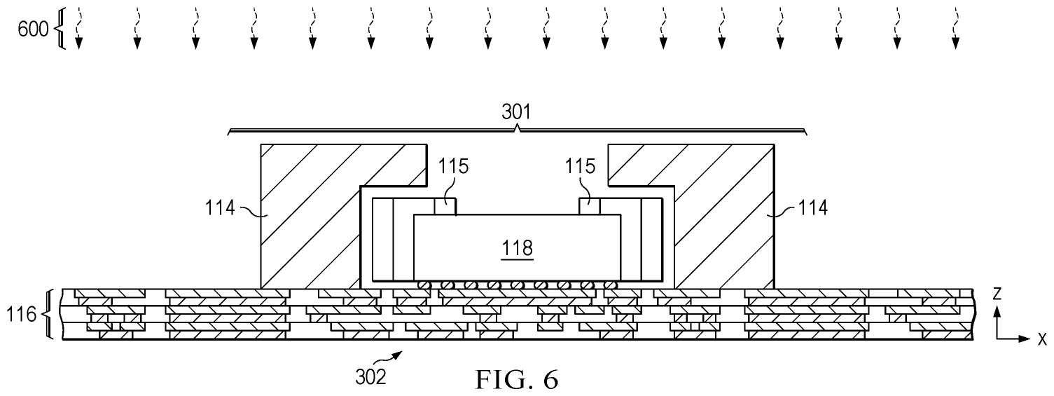

At 206 in FIG. 2, the method 200 includes forming electrical connections for the various components 114, 115, and 118 in each unit area 301 of the panel array. FIG. 6 shows one example, in which a thermal solder reflow process 600 is performed that reflows the previously formed solder and forms solder connections between the corresponding conductive features of the substrate 116 and the components 114, 115, and 118 in each unit area 301.

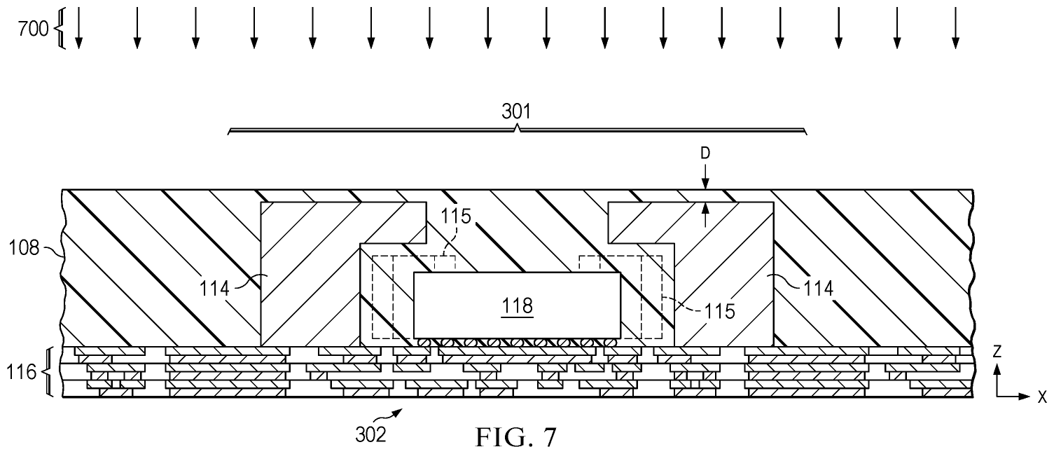

The method 200 continues at 208 in FIG. 2 with molding to form the molded package structure 108 that encloses the semiconductor die 118, the capacitors 115, and the conductive metal clips 114. FIG. 7 shows one example, in which a molding process 700 is performed that forms the molded package structure 108. The molding process 700 uses a mold (not shown) having a top cavity surface that is positioned during the process 700 above (i.e., spaced apart from) the top sides of the conductive metal clips 114 along the third direction Z in the illustrated orientation. As shown in FIG. 7, this provides an initial molded structure 108 that covers the top sides of the conductive metal clips 114, for example, by the spacing distance D described above in connection with FIG. 1A.

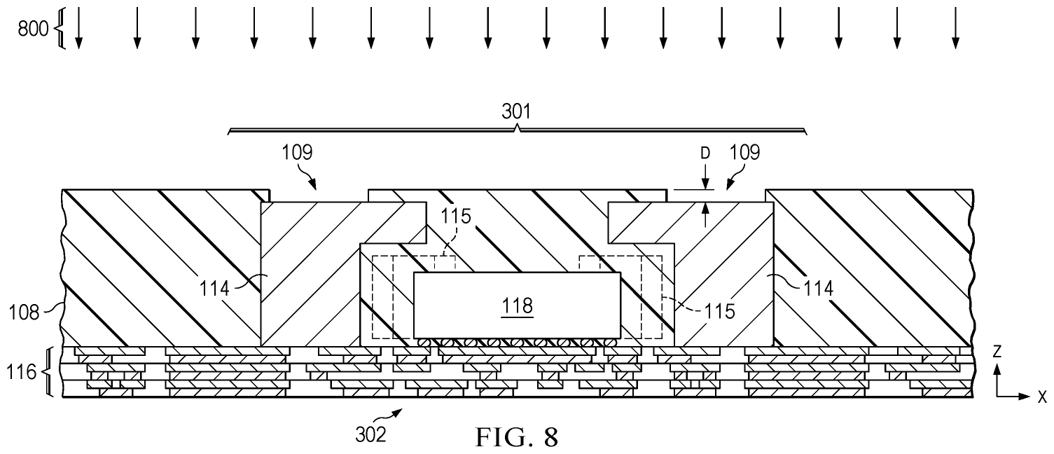

At 210 in FIG. 2, the method 200 continues with removing molding material to form the recesses 109 in the top side of the molded structure 108 to expose the top sides of the conductive metal clips 114. FIG. 8 shows one example, in which a material removal process 800 is performed that forms the recesses 109 in the top side of the molded structure 108 and exposes the top sides of the conductive metal clips 114. In one example, the material removal process 800 is a laser ablation process that uses a laser (not shown) to selectively ablate portions of the molded material 108 above at least a portion of each of the conductive metal clips 114. The laser ablation process 800 in this example provides a clean surface at the top sides of the conductive metal clips 114 and creates the recesses 109 having a recessed depth D as shown in FIG. 8.

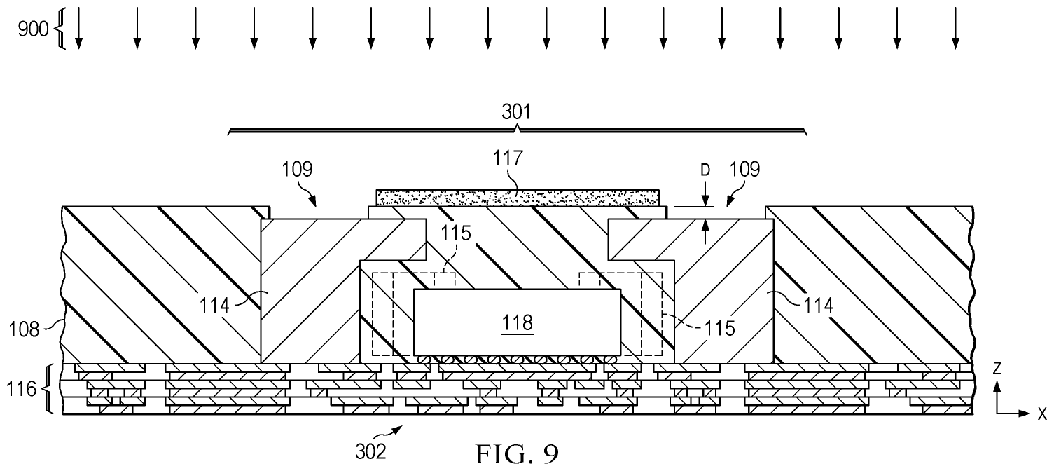

In one example, the method 200 includes optional adhesive formation at 211 in FIG. 2. FIG. 9 shows one example, in which an adhesive formation process 900 is performed that forms the adhesive 117 on a portion of the top side of the molded package structure 108 in each unit area 301 of the panel array. Any suitable adhesive formation process 900 and adhesive material 117 can be used, for example, silk-screening, printing, dispensing, etc. of glue, UV or thermally activated adhesive 117. In another implementation, the adhesive formation at 211 can be omitted.

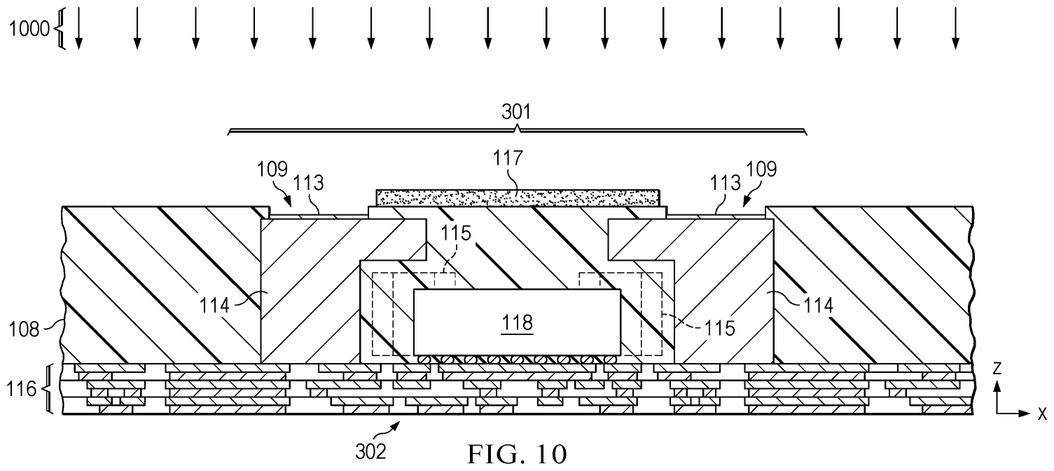

The method 200 continues at 212 in FIG. 2 with solder paste formation. When an adhesive is included in the assembly, the adhesive formation at 211 and the solder paste formation at 212 can be in any suitable order. FIG. 10 shows one example, in which a solder paste formation process 1000 is performed that forms the solder paste 113 on exposed portions of the top sides of the conductive metal clips 114 in each unit area 301 of the panel array. Any suitable formation process 1000 can be used, for example, silk-screening using a stencil, printing, dispensing, etc. in order to form the solder paste 113 on the top sides of the first and second metal clips 114 exposed in the respective recesses 109 of the molded package structure 108. In one example, the solder paste 114 is formed at 212 by printing the solder paste 113 on the top sides of the first and second metal clips 114 exposed in the respective recesses 109. In another example, the solder paste formation at 212 includes silk screening the solder paste 113 on the top sides of the first and second metal clips 114 exposed in the respective recesses 109.

Unlike alternative approaches where the metal clip top surfaces are not over molded and are approximately flush with the top side of the molded package structure 108, the recesses 109 created after over molding the metal clip tops facilitate proper solder connections between the electronic component terminals 111 and the top sides of the conductive metal clips 114. In particular, the recesses 109 provide channels that facilitate formation of the solder 113 along at least portions of the top sides of the prospective conductive metal clips 114. The recesses also mitigate or prevent the weight of the subsequently attached electronic component 110 from causing lateral solder paste movement during solder reflow. This helps ensure the proper final solder thickness (e.g., along the third direction Z) to prevent or mitigate nonwetted solder joints and help to ensure robust attachment and mechanical support of the electronic component 110 on the electronic device 100, whether alone or in combination with any included adhesive 117. In addition, examples where the recesses 109 are formed by laser ablation or other clean material removal process helps to provide a clean surface along the exposed top sides of the conductive metal clips 114 to further facilitate proper solder connections between the electronic component terminals 111 and the top sides of the conductive metal clips 114.

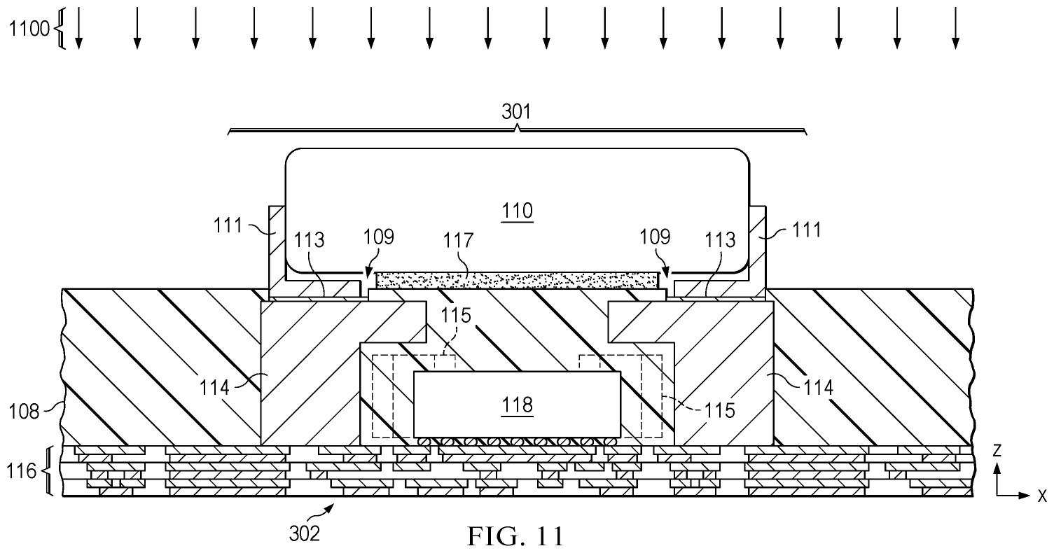

The method 200 continues at 214 and 216 in FIG. 2 to both mechanically and electrically connect the electronic component 110 and the terminals 111 thereof. In the illustrated example, the electrical connection processing includes attaching the external electronic component 110 at 214 in FIG. 2. FIG. 11 shows one example, in which an attachment process 1100 is performed, for example using automated pick and place equipment (not shown) that attaches the first and second terminals 111 of the electronic component 110 through the recesses 109 to the solder paste 113 on the top sides of the respective first and second metal clips 114. In the illustrated example, the attachment process 1100 also engages a portion of the bottom side of the electronic component 110 to the adhesive 117 as shown in FIG. 11.

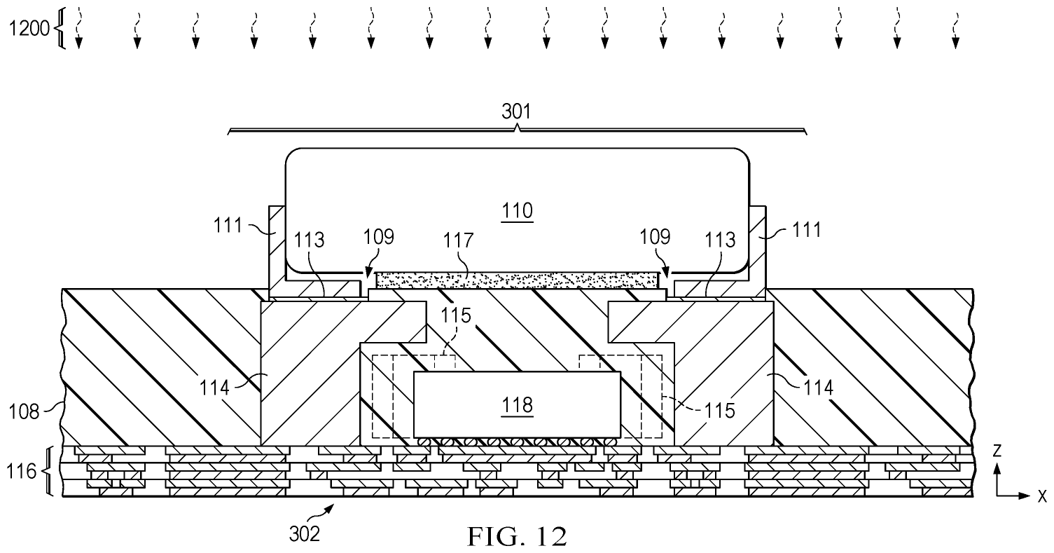

At 216 in FIG. 2, the example implementation of the method 200 includes completing electrical interconnection of the component terminals 111 to the top sides of the metal clips 114 by reflowing the solder paste 113. FIG. 12 shows one example, in which a thermal reflow process 1200 is performed that reflows the solder paste 113 and electrically connects the conductive metal first and second terminals 111 of the electronic component 110 through the recesses 109 to the top sides of the respective first and second metal clips 114. In this example, the thermal process 1200 reflows the solder paste 113 to form solder connections between the first and second terminals 111 of the electronic component 110 and the top sides of the respective first and second metal clips 114. Where thermally activated adhesive 117 is used, the reflow process 1200 also activates and cures the adhesive 117. A separate adhesive activation and/or curing process or processes (not shown) can be used to activate and/or cure any included adhesive 117 in certain examples (e.g., thermal curing or activation, UV curing or activation, etc.).

In one example, the method 200 in FIG. 2 can include optional additional molding processing at 217. FIG. 13 shows one example, in which a second molding process 1300 is performed that forms a second molded package structure 1308 that encloses the electronic component 110 and covers a portion of the top side of the first or bottom molded package structure 108. This can provide additional protection and/or electrical isolation for the added electronic component 110. In another implementation, the second molding processing at 217 in FIG. 2 can be omitted.

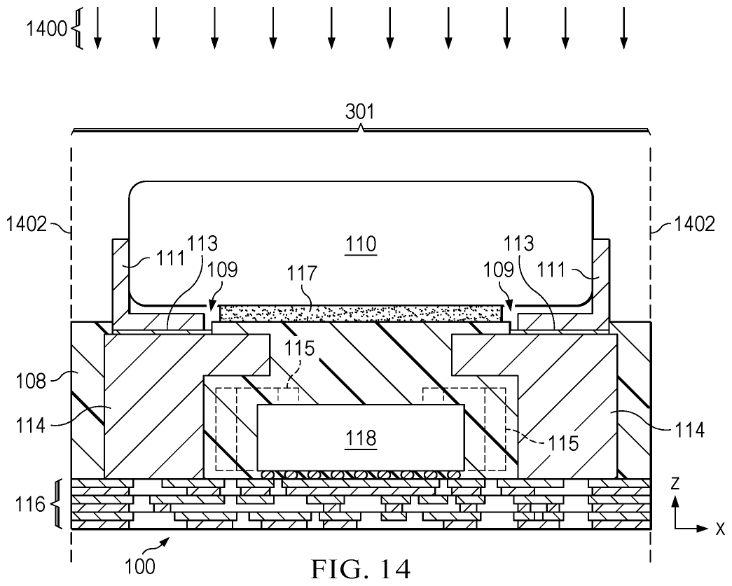

The method 200 continues at 218 in FIG. 2 with package separation processing. In the illustrated example, the packaged electronic devices in each unit area 301 are concurrently or sequentially processed with the individual portions of the substrate 116 formed in a contiguous substrate structure having rows and columns of the unit areas 301. The separation processing at 218 in FIG. 2 separates individual instances of the finished packaged electronic device 100 from the panel array structure. Any suitable package separation process or processes can be used. FIG. 14 shows one example, in which a package separation process 1400 is performed, such as saw cutting, laser cutting, etching, etc. that separates the finished electronic device 100 from the panel array structure. In this implementation, a cutting process 1400 is used which cuts along scribe lines 1402 between unit areas 301 along the row and column directions of the multilevel package substrate panel array structure.

Described examples include creating the package structure recesses 109, for example, through laser ablation or other suitable technique, to remove molding compound or other material from an initially over molded from parentheses e.g., covered) clip 114. Described implementations avoid problems associated with attempting to perform molding operations with a mold engaged to the top sides of the clip, which can require complex and expensive dual film assisted molding (FAM) techniques and equipment and facilitate easy adaptation for dimensional tolerance variations during manufacturing while helping reduce the total electronic device height along the Z-direction. The described examples also provide benefits associated with the recesses 109, including the recessed channel structure that helps contain solder paste and ensure desired solder thickness and robust mechanical mounting of the electronic component 110. In addition, laser ablation example implementations facilitate reduction or avoidance of residual molding material on the top sides of the clips 114 and enhance the solder connections between the component terminals 111 and the conductive metal clips 114. The described examples help enhance manufacturing yield and reduce manufacturing cost while providing a robust electronic device structure, even where the electronic component 110 has a large vertical height along the Z-direction to produce a potentially high aspect ratio electronic device 100 while reducing the chance of detachment of the electronic component 110 from the electronic device 100.

Modifications are possible in the described examples, and other implementations are possible, within the scope of the claims.

What is claimed is:

1. An electronic device, comprising:
a semiconductor die attached to a lead frame or substrate;
conductive first and second metal clips attached to the lead frame or substrate;
a molded package structure that encloses the semiconductor die and has a top side with first and second recesses that extend into the molded package structure to top sides of the respective first and second metal clips; and
an electronic component having conductive metal first and second terminals that extend into the respective first and second recesses and are electrically connected to the top sides of the respective first and second metal clips.

2. The electronic device of claim 1, wherein the electronic component is a passive surface mount technology component having a first terminal extending into the first recess and electrically connected to the top side of the first metal clip, and a second terminal extending into the second recess and electrically connected to the top side of the second metal clip.

3. The electronic device of claim 1, wherein the electronic component is one of a resistor, a capacitor, an inductor, a diode, and a transistor.

4. The electronic device of claim 1, comprising an adhesive extending between the top side of the molded package structure and a side of the electronic component.

5. The electronic device of claim 4, comprising a second molded package structure that encloses the electronic component.

6. The electronic device of claim 1, comprising a second molded package structure that encloses the electronic component.

7. A system, comprising:
a circuit board having conductive metal pads; and
an electronic device attached to the circuit board and comprising:
conductive metal leads electrically connected to respective ones of the conductive metal pads;
a semiconductor die attached to a lead frame or substrate;
conductive first and second metal clips attached to the lead frame or substrate;
a molded package structure that encloses the semiconductor die and has a top side with first and second recesses that extend into the molded package structure to top sides of the respective first and second metal clips; and
an electronic component having conductive metal first and second terminals that extend into the respective first and second recesses and are electrically connected to the top sides of the respective first and second metal clips.

8. The system of claim 7, wherein the electronic component is a passive surface mount technology component having a first terminal extending into the first recess and electrically connected to the top side of the first metal clip, and a second terminal extending into the second recess and electrically connected to the top side of the second metal clip.

9. The system of claim 7, wherein the electronic component is one of a resistor, a capacitor, an inductor, a diode, and a transistor.

10. The system of claim 7, comprising an adhesive extending between the top side of the molded package structure and a side of the electronic component.

11. The system of claim 10, comprising a second molded package structure that encloses the electronic component.

12. The system of claim 1, comprising a second molded package structure that encloses the electronic component.

13. A method of fabricating an electronic device, the method comprising:
attaching a semiconductor die to a lead frame or substrate;
attaching conductive first and second metal clips to the lead frame or substrate;
forming a molded package structure that encloses the semiconductor die and has a top side;
removing molded material from a top side of the molded package structure to form first and second recesses that extend into the molded package structure to top sides of the respective first and second metal clips; and
electrically connecting conductive metal first and second terminals of an electronic component through the recesses to the top sides of the respective first and second metal clips.

14. The method of claim 13, wherein removing molded material from the top side of the molded package structure includes performing a laser ablation process.

15. The method of claim 14, further comprising:
forming an adhesive on a portion of the top side of the molded package structure; and
engaging a portion of a side of the electronic component to the adhesive.

16. The method of claim 15, wherein electrically connecting the first and second terminals includes:
forming solder paste on the top sides of the first and second metal clips exposed in the respective recesses;
attaching the first and second terminals of the electronic component through the recesses to the solder paste on the top sides of the respective first and second metal clips; and
reflowing the solder paste to form solder connections between the first and second terminals of the electronic component and the top sides of the respective first and second metal clips.

17. The method of claim 13, further comprising forming a second molded package structure that encloses the electronic component and covers a portion of the top side of the molded package structure.

18. The method of claim 13, wherein electrically connecting the first and second terminals includes:
printing solder paste on the top sides of the first and second metal clips exposed in the respective recesses;
attaching the first and second terminals of the electronic component through the recesses to the solder paste on the top sides of the respective first and second metal clips; and
reflowing the solder paste to form solder connections between the first and second terminals of the electronic component and the top sides of the respective first and second metal clips.

19. The method of claim 13, wherein electrically connecting the first and second terminals includes:
silk screening solder paste on the top sides of the first and second metal clips exposed in the respective recesses;
attaching the first and second terminals of the electronic component through the recesses to the solder paste on the top sides of the respective first and second metal clips; and
reflowing the solder paste to form solder connections between the first and second terminals of the electronic component and the top sides of the respective first and second metal clips.

20. The method of claim 13, further comprising:
forming an adhesive on a portion of the top side of the molded package structure; and
engaging a portion of a side of the electronic component to the adhesive.
